(19) United States
(12) Patent Application Publication
(10) Pub. No.: US 2018/0323393 A1
(43) Pub. Date: Nov. 8, 2018

(54) ORGANIC LIGHT-EMITTING DISPLAY APPARATUS

(71) Applicant: Wuha China Star Optoelectronics Technology Co., Ltd., Wuhan City (CN)

(72) Inventors: Jinchang HUANG, Wuhan City (CN); Hsianglun HSU, Wuhan City (CN)

(73) Assignee: Wuhan China Star Optoelectronics Technology Co., Ltd.

(21) Appl. No.: 15/547,805

(22) PCT Filed: Jun. 14, 2017
(86) PCT No.: PCT/CN2017/088331

§ 371 Date: Aug. 1, 2017

(30) Foreign Application Priority Data
May 3, 2017 (CN) 201710305259.0

(51) Int. Cl. H01L 51/50; H01L 27/32

(52) U.S. Cl. CPC H01L 51/5024; H01L 51/5088; H01L 51/5056; H01L 27/3244; H01L 51/5092; H01L 51/5096; H01L 51/5016; H01L 51/5072

(57) ABSTRACT

The present invention provides an organic light-emitting display apparatus where an organic light-emitting device comprises an anode layer, a cathode layer, and an organic light-emitting dielectric layer disposed between the anode layer and the cathode layer; organic light-emitting dielectric layer comprises a hole injection layer, a hole transporting layer, a first mixed layer, an emission layer, an electron transporting layer and an electron injection layer sequentially disposed; wherein first mixed layer consists of bipolar host material having function of simultaneously transporting hole and electron, and is doped with either of a material having an electron blocking function and a material having a hole control function. It can decrease injection barrier of carriers of holes and electrons in the organic light-emitting device, control carrier injection rate and position of carrier recombination region, and raise the recombination efficiency of the carriers, thereby achieving a high efficiency, long lifetime organic light-emitting device.

### FIELD OF THE INVENTION

The present invention relates to a display technology field, and more particular to an organic light-emitting display apparatus.

### BACKGROUND OF THE INVENTION

Organic light-emitting display (OLED) technology is commonly known in this field, which possesses self-luminous property with differing from the liquid crystal display (LCD) technology. OLED does not need additional backlight. Besides, OLED further has a thin thickness, light weight, driving voltage, lower power consumption, high illumination efficiency, short response time, high clarity and contrast, near 180° view angle, wide range of working temperature, applicability of flexible display and large scale full color display. OLED has been regard as the most potential display apparatus.

Organic light-emitting display apparatus are classified into two types, active type and passive type, wherein active type planar display has lots of advantages of a compact body, power saving etc., thereby achieving broad applications. The current active type organic light-emitting display apparatus principally comprises a base substrate, a thin film transistor (TFT) layer disposed above the base substrate, an organic light-emitting component disposed on the TFT layer, and an encapsulation layer disposed above the organic light-emitting component, for implementing encapsulation thereto; wherein the TFT layer serves to drive the organic light-emitting component, whereas the organic light-emitting component commonly comprises pixel electrode and common electrode which respectively act as anode and cathode, and an organic luminous functional layer disposed between the pixel electrode and the common electrode such that when proper voltage are applied onto anode and cathode, light is emitted from organic luminous functional layer. The organic luminous functional layer commonly comprises a hole injection layer disposed above the anode, a hole transporting layer disposed above the hole injection layer, an emission layer dispose above the hole transporting layer, an electron transporting layer disposed above the emission layer, an electron injection layer disposed above the electron transporting layer. Its luminous principle is that under certain voltage driving, electrons and holes are respectively injected from the cathode and a the node to the electron injection layer and the hole injection layer, electrons and holes respectively pass through the electron transporting layer and the hole transporting layer to migrate into the emission layer, and meet with each other in the emission layer, so as to form excitions to excite luminescent molecules. The latter emits visible lights through radiative relaxation.

Currently, it is essential to resolve a long-time technical issue of the organic light-emitting display apparatus that efficiency and lifetime of the organic light-emitting device are lowered.

### SUMMARY OF THE INVENTION

An objective of the present invention is to provide an organic light-emitting display apparatus which collocates different-function organic compound films to decrease the injection barrier of carriers in organic light-emitting device, control the injection rate of the carriers and the location of carrier recombination region, and raise the recombination efficiency of the carriers, thereby achieving a high-efficiency, long-lifetime organic light-emitting device.

To accomplish the aforementioned objective, the present invention provides an organic light-emitting display apparatus, which comprises a substrate, and an organic light-emitting device disposed on the substrate;

said organic light-emitting device comprises a anode layer, a cathode layer, and an organic light-emitting dielectric layer disposed between the anode layer and the cathode layer;

said organic light-emitting dielectric layer comprises a hole injection layer, a hole transporting layer, a first mixed layer, an emission layer, an electron transporting layer and an electron injection layer, which are sequentially disposed on said anode layer, nearly to a side of the cathode layer;

said first mixed layer is a mixed material layer consisting of a bipolar host material and a first functional doping material; wherein said bipolar host material is a compound having a function of simultaneously transporting hole and electron; said first functional doping material is a material having an electron blocking function, a material having a hole control function, or both thereof in combination.

Said organic light-emitting dielectric layer further comprises a second mixed layer disposed between said emission layer and the electron transporting layer; and said second mixed layer consists of the bipolar host material.

Said second mixed layer is a mixed material layer further consisting of a second functional doping material; wherein said second functional doping material is a material having a hole blocking function, a material having an electron control function, or both thereof in combination.

Said emission layer is a mixed material layer consisting of the bipolar host material and a luminescent dopant; and

said first mixed layer, the emission layer, and the second mixed layer commonly constitute a mixed layer unit; a thickness of said first mixed layer, a thickness of said second mixed layer do not respectively exceed one-third in a thickness proportion to the entire mixed layer unit.

Said luminescent dopant is triplet excited state phosphorescent emission, singlet excited state fluorescence emission, or thermally activated delayed fluorescence emission.

A thickness of said first mixed layer is 10-500 Å, which is doped with the first functional doping material in a weight percent ratio of 1%-50%.

A thickness of said second mixed layer is 10-500 Å.

Said second mixed layer is doped with the second functional doping material in a weight percent ratio of 1%-50%.

The hole injection layer, the hole transporting layer, the first mixed layer, the emission layer, the electron transporting layer, the electron injection layer and the second mixed layer in said organic light-emitting dielectric layer all are made and formed by a vacuum deposition method, an inkjet printing method, a knife coating method, a spin coating method, or a screen printing method.

Said substrate is a TFT substrate;

an anode layer, an organic light-emitting dielectric layer, and a cathode layer are, which are sequentially disposed on said substrate from bottom to top in said organic light-emitting device; or

a cathode layer, an organic light-emitting dielectric layer, and an anode layer are, which are sequentially disposed on said substrate from bottom to top in said organic light-emitting device.

The present invention further provides an organic light-emitting display apparatus, which comprises a substrate, and an organic light-emitting device disposed on the substrate;

Said organic light-emitting device comprises an anode layer, a cathode layer, and an organic light-emitting dielectric layer disposed between the anode layer and the cathode layer;

Said organic light-emitting dielectric layer comprises a hole injection layer, a hole transporting layer, a first mixed layer, an emission layer, an electron transporting layer, and an electron injection layer, which are sequentially disposed on said anode layer, nearly to a side of cathode layer;

said first mixed layer is a mixed material layer consisting of the bipolar host material and a first functional doping material; wherein said bipolar host material is a compound having a function of simultaneously transporting hole and electron; said first functional doping material is a material having an electron blocking function, a material having a hole control function, or both thereof in combination;

wherein a thickness of said first mixed layer is 10-500 Å, which is doped with the first functional doping material in a weight percent ratio of 1%-50%; and

wherein said substrate is a TFT substrate;

in said organic light-emitting device, the anode layer, the organic light-emitting dielectric layer, and the cathode layer are sequentially disposed on said substrate from bottom to top; or

in said organic light-emitting device, the cathode layer, the organic light-emitting dielectric layer and the anode layer are sequentially disposed on said substrate from bottom to top.

A beneficial effect of the present invention is that: the present invention provides an organic light-emitting display apparatus where an organic light-emitting device comprises an anode layer, a cathode layer, and an organic light-emitting dielectric layer disposed between the anode layer and the cathode layer; said organic light-emitting dielectric layer comprises a hole injection layer, a hole transporting layer, a first mixed layer, an emission layer, an electron transporting layer, and an electron injection layer sequentially disposed thereon; wherein said first mixed layer consists of a bipolar host material having a function of simultaneously transporting hole and electron, and is doped with either of a material having an electron blocking function and a material having a hole control function. It can decrease injection barrier of carriers of holes and electrons in the organic light-emitting device, control carrier injection rate and position of carrier recombination region, and raise the recombination efficiency of the carriers, thereby achieving a high efficiency, long lifetime organic light-emitting device.

For better realizing the characteristic and the technical context of the present invention, please refer to the detailed description in regard to the present invention with the accompanying drawings; however, the accompanying drawings just for reference and explanation but not for limitation to the present invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural schematic diagram of a first embodiment of an organic light-emitting display apparatus of the present invention;

FIG. 2 is a structurally schematic diagram of a second embodiment of an organic light-emitting display apparatus of the present invention;

FIG. 3 is a structurally schematic diagram of a third embodiment of organic light-emitting display apparatus of the present invention; and

FIG. 4 is a structurally schematic diagram of a fourth embodiment of an organic light-emitting display apparatus of the present invention.

### DETAILED DESCRIPTION OF PREFERRED EMBODIMENTS

For better explaining the technical solution and the effect of the present invention, the present invention will be further described in detail with the accompanying drawings and the specific embodiments.

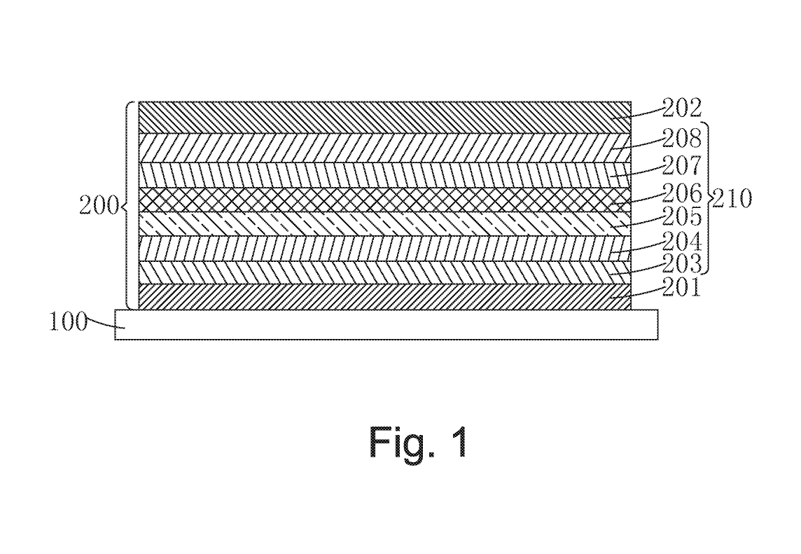

Referring to FIG. 1, which is a structural schematic diagram of a first embodiment of an organic light-emitting display apparatus of the present invention, said organic light-emitting display apparatus comprises a substrate 100, and an organic light-emitting device 200 disposed on the substrate 100 in this embodiment;

said organic light-emitting device 200 comprises an anode layer 201, a cathode layer 202, and an organic light-emitting dielectric layer 210 between disposed on the anode layer 201 and the cathode layer 202;

said organic light-emitting dielectric layer 210 comprises a hole injection layer 203, a hole transporting layer 204, a first mixed layer 205, an emission layer 206, an electron transporting layer 207 and an electron injection layer 208, which are sequentially disposed on said anode layer 201, nearly to a side of the cathode layer 202;

said first mixed layer 205 is a mixed material layer consisting of the bipolar host material and a first functional doping material; wherein said bipolar host material is a compound having a function of simultaneously transporting hole and electron, the bipolar host material can simultaneously transport hole and electron. For example, said bipolar host material can be 4,7-di-carbazol-9-yl-[1,10]-phenanthroline (as abbreviated to ‘BUPH1’), 2,5-BIS (2-(9H-carbazol-9-yl)phenyl)-1,3,4-oxadiazole (as abbreviated to ‘o-CzOXD’), or N-(4-diphenylphosph-oryphenyl carbazole (as abbreviated to ‘MOP12’) etc.

Said first functional doping material is a material having an electron blocking function, a material having a hole control function, or both thereof in combination; namely, said first mixed layer 205 can be doped thereinto with a material having the electron blocking function, for blocking injected electrons from passing through the emission layer 206 from the cathode 202 to reach a side of the hole transporting layer 204; or

said first mixed layer 205 can be also doped thereinto with a material having the hole control function, for controlling a rate of injecting the hole carriers from the hole transporting layer 204 to the emission layer 206; or

said first mixed layer 205 can be also doped thereinto with a material having the electron blocking function and a material having the hole control function at the same time, so as to accomplish blocking injected electrons from passing through the emission layer 206 from the cathode 202 to reach a side of the hole transporting layer 204, and for controlling a rate of injecting the hole carriers from the hole transporting layer 204 to the emission layer 206 at the same time.

Specifically, a material of said hole transporting layer 204 has a hole transporting function, as a hole transporting material; a material of said hole injection layer 203 has a hole injecting function, as a hole injecting material; a material of said hole transporting layer 204 has a higher or identical ionization potential than a material of said hole injection layer 203. A material of said electron transporting layer 207 has an electron transporting function, as an electron transporting material; a material of said electron injection layer 208 has an electron injecting function, as an electron injecting material.

Specifically, in said first mixed layer 205, a material having the electron blocking function has the highest Occupied Molecular Orbital (HOMO) and the lowest Unoccupied Molecular Orbital (LUMO) energy level difference greater than those of the hole transporting material and the electron transporting material; a material having the hole control function has a hole transport rate slower than that of a hole transporting material.

Specifically, a thickness of said first mixed layer 205 is 10-500 Å, which is doped with the first functional doping material in a weight percent ratio of 1%-50%; namely, while said first functional doped material is a material having the electron blocking function, said material having the electron blocking function has a weight percent ratio of 1%-50% doped into the first mixed layer 205; while said first functional doped material is a material having the hole control function, said material having the hole control function has a weight percent ratio of 1%-50% doped into the first mixed layer 205; while said first functional doped material is a combination of a material having the electron blocking function and a material having the hole control function, said material having the electron blocking function and the material having the hole control function all have a weight percent ratio of 1%-50% doped into the first mixed layer 205, a weight percent ratio of the sum of both thereof in the first mixed layer 205 is also 1%-50%.

Specifically, said substrate 100 is a TFT substrate; said substrate 100 can be either a rigid substrate or a flexible substrate.

Specifically, said organic light-emitting device 200 can be an upright device, wherein the anode layer 201, the organic light-emitting dielectric layer 210, and the cathode layer 202 are sequentially disposed on said substrate 100 from bottom to top; the hole injection layer 203 in said organic light-emitting dielectric layer 210 is made and formed above the anode layer 201 on said substrate 100 by a vacuum deposition method (Vacuum Evaporation), an inkjet printing method (Ink-jet Printing), a knife coating method (Blade Coating), a spin coating method (Spin-Coating), a screen printing method (Screen Printing) etc. method, it preferably alters vacuum deposition method for making formation of the hole injection layer 203 with micromolecule material.

Specifically, the other organic compound film, the hole transporting layer 204, the first mixed layer 205, the emission layer 206, the electron transporting layer 207, and the electron injection layer 208 in said organic light-emitting dielectric layer 210 are also made and formed by the fabricating method as making the hole injection layer 203, all of which can be made and formed by the vacuum deposition method, the inkjet printing method, the knife coating method, the spin coating method or the screen printing method.

Alternatively, said organic light-emitting device 200 can be also an inverted device, wherein the cathode layer 202, the organic light-emitting dielectric layer 210, and the anode layer 201 are sequentially disposed on said substrate 100 from bottom to top.

Specifically, said organic light-emitting device 200 can be a red, green, blue, and the colour organic light-emitting devices.

Specifically, said organic light-emitting device 200 can be either a bottom-emission light-emitting device that emits light from the substrate 100, or also a top-emission light-emitting device that emits light from a side departed away from the substrate 100.

The organic light-emitting display apparatus of the present invention, by collocating different-function organic compound films in the organic light-emitting device 200, decreases injecting barrier of carriers (holes and electrons) in the organic light-emitting device, controls carrier injection rate and position of carrier recombination region, and raises the recombination efficiency of the carriers, thereby achieving a high efficiency, long lifetime organic light-emitting device 200.

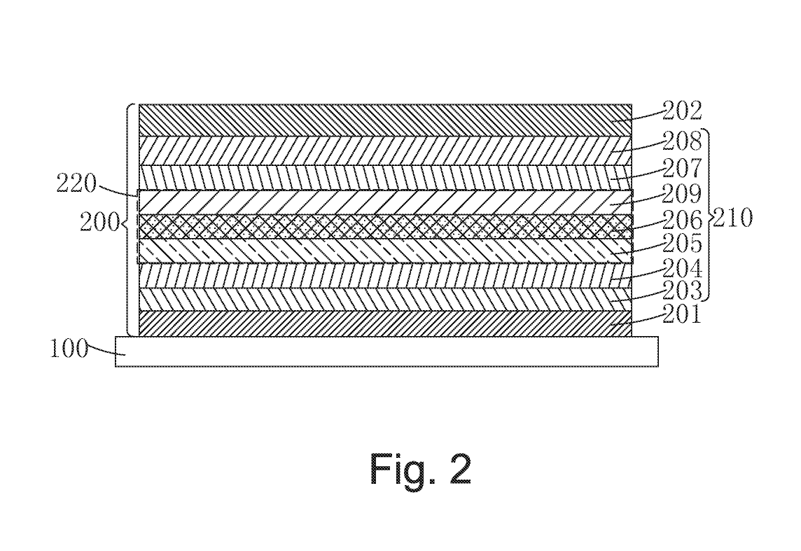

Referring to FIG. 2, which is a structurally schematic diagram of a second embodiment of an organic light-emitting display apparatus of the present invention. This embodiment is contrasted with the aforementioned first embodiment in that, said organic light-emitting dielectric layer 210 further comprises a second mixed layer 209 disposed between said emission layer 206 and the electron transporting layer 207; said second mixed layer 209, as well as said first mixed layer 205, also consists of the bipolar host material capable of simultaneously transporting hole and electron. Said emission layer 206 identically also consists of the bipolar host material, which is doped thereinto with a luminescent dopant thereby having a luminous function; whereby said first mixed layer 205, the emission layer 206 and the second mixed layer 209 commonly constitute a mixed layer unit 220, which respectively serve to a first section, a second section and a third section in said mixed layer unit 220.

Specifically, a luminescent dopant in said emission layer 206 is triplet excited state phosphorescent emission, singlet excited state fluorescence emission or thermally activated delayed fluorescence emission.

Specifically, in said mixed layer unit 220, a thickness of said first mixed layer 205, a thickness of said second mixed layer 209 do not respectively exceed one-third in a thickness proportion to the entire mixed layer unit 220.

Specifically, a thickness of said second mixed layer 209 is 10-500 Å.

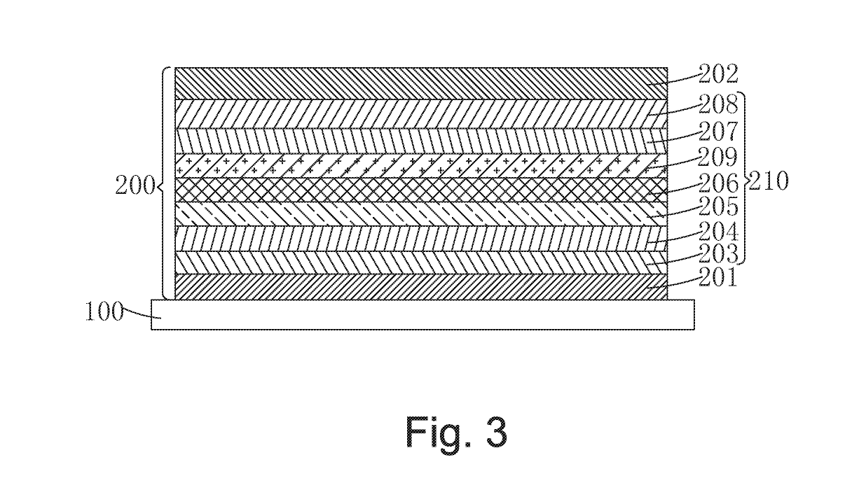

Referring to FIG. 3, which is a structurally schematic diagram of a third embodiment of an organic light-emitting display apparatus of the present invention. This embodiment is contrasted with the aforementioned first embodiment in that, said organic light-emitting dielectric layer 210 further comprises a second mixed layer 209 disposed between said emission layer 206 and the electron transporting layer 207; and said second mixed layer 209, as well as said first mixed layer 205, also consists of the bipolar host material capable of simultaneously transporting hole and electron, and is doped thereinto with a second functional doping material; said second functional doping material is a material having a hole blocking function, a material having an electron control function, or both thereof in combination; namely, said second mixed layer 209 can be doped thereinto with a material having a hole blocking function, for blocking injected hole from passing through the emission layer 206 from the anode 201 to reach a side of the electron transporting layer 207; or

said second mixed layer 209 can also be doped thereinto with a material having an electron control function, for controlling a rate of injecting the electron carriers from the electron transporting layer 207 to the emission layer 206; or furthermore

said second mixed layer 209 can be also doped thereinto with a material having a hole blocking function and a material having an electron control function at the same time, for blocking injected holes from passing through the emission layer 206 from the anode 201 to reach a side of the electron transporting layer 207, and for controlling a rate of injecting the electron carriers from electron transporting layer 207 to the emission layer 206 at the same time.

Specifically, in said second mixed layer 209, a material having a hole blocking function has the highest Occupied Molecular Orbital and the lowest Unoccupied Molecular Orbital energy level difference, greater than those of the hole transporting material and the electron transporting material, a material having an electron control function has a electron transport rate slower than that of an electron transporting material.

Specifically, a thickness of said second mixed layer 209 is 10-500 Å, which is doped with the second functional doping material in a weight percent ratio of 1%-50%; namely, while said second functional doped material is a material having a hole blocking function, said material having a hole blocking function has a weight percent ratio of 1%-50% doped into the second mixed layer 209; while said second functional doped material is a material having an electron control function, said material having an electron control function has a weight percent ratio of 1%-50% doped into the second mixed layer 209; while said second functional doped material is combination of a material having a hole blocking function and a material having an electron control function, said material having a hole blocking function and the material having an electron control function all have a weight percent ratio of 1%-50% doped into the second mixed layer 209, a weight percent ratio of the sum of both thereof in the second mixed layer 209 is also 1%-50%.

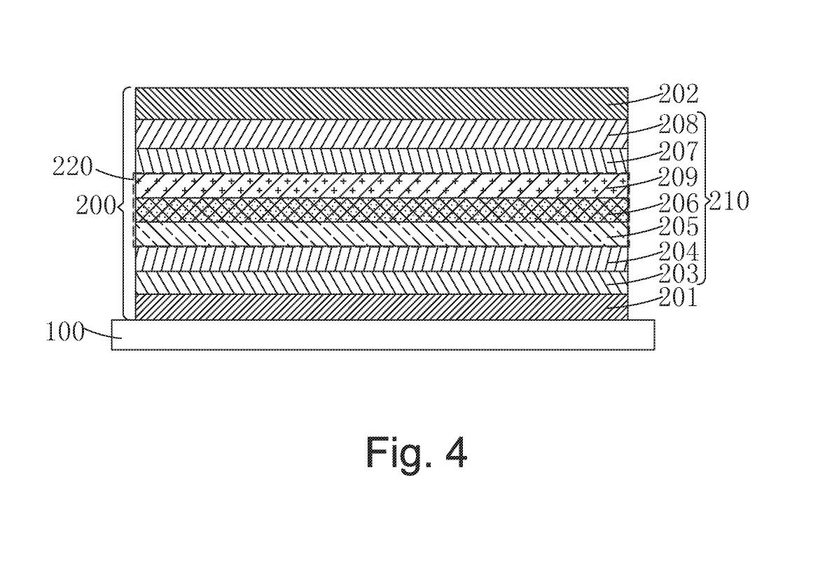

Referring to FIG. 4, which is a structurally schematic diagram of a fourth embodiment of an organic light-emitting display apparatus of the present invention. This embodiment is contrasted with the aforementioned third embodiment in that, said emission layer 206 identically also consists of the bipolar host material, which is doped with a luminescent dopant thereby having a luminous function; whereby said first mixed layer 205, the emission layer 206 and the second mixed layer 209 commonly constitute a mixed layer unit 220, which respectively serve to a first section, a second section and a third section in said mixed layer unit 220.

Specifically, a luminescent dopant in said emission layer 206 is triplet excited state phosphorescent emission, singlet excited state fluorescence emission or thermally activated delayed fluorescence emission.

Specifically, in said mixed layer unit 220, a thickness of said first mixed layer 205, a thickness of said second mixed layer 209 do not respectively exceed one-third in a thickness proportion to the entire mixed layer unit 220.

In conclusion, an organic light-emitting display apparatus is provided by the present invention, where an organic light-emitting device comprises an anode layer, a cathode layer, and an organic light-emitting dielectric layer disposed between the anode layer and the cathode layer; said organic light-emitting dielectric layer comprises a hole injection layer, a hole transporting layer, a first mixed layer, an emission layer, an electron transporting layer, and an electron injection layer sequentially disposed thereon; wherein said first mixed layer consists of a bipolar host material having a function of simultaneously transporting hole and electron, and is doped with either of a material having an electron blocking function and a material having a hole control function. It can decrease injection barrier of carriers of holes and electrons in the organic light-emitting device, control carrier injection rate and position of carrier recombination region, and raise the recombination efficiency of the carriers, thereby achieving a high efficiency, long lifetime organic light-emitting device.

As above mentioned, in accordance with technical embodiments and technical solution of the present invention, to any persons who are ordinary skilled in the art, other related change or variances can be made which should be covered by the protected scope of the subject claims attached below by the present invention.

What is claimed is:

1. An organic light-emitting display apparatus comprising a substrate, and an organic light-emitting device disposed on the substrate;
said organic light-emitting device comprising an anode layer, a cathode layer, and an organic light-emitting dielectric layer disposed between the anode layer and the cathode layer;
said organic light-emitting dielectric layer comprising a hole injection layer, a hole transporting layer, a first mixed layer, an emission layer, an electron transporting layer, and an electron injection layer, which are sequentially disposed on said anode layer, nearly to a side of the cathode layer; and
said first mixed layer being a mixed material layer consisting of a bipolar host material and a first functional doping material; wherein said bipolar host material is a compound having a function of simultaneously transporting hole and electron; said first functional doping material is a material having an electron blocking function, a material having a hole control function, or both thereof in combination.

2. Said organic light-emitting display apparatus as claimed in claim 1, wherein said organic light-emitting dielectric layer further comprises a second mixed layer disposed between said emission layer and the electron transporting layer; and said second mixed layer consists of the bipolar host material.

3. Said organic light-emitting display apparatus as claimed in claim 2, wherein said second mixed layer is a mixed material layer further consisting of a second functional doping material; wherein said second functional doping material is a material having a hole blocking function, a material having an electron control function, or both thereof in combination.

4. Said organic light-emitting display apparatus as claimed in claim 2, wherein said emission layer is a mixed material layer consisting of the bipolar host material and a luminescent dopant; and
said first mixed layer, the emission layer, and the second mixed layer commonly constitute a mixed layer unit; a thickness of said first mixed layer, a thickness of said second mixed layer do not respectively exceed one-third in a thickness proportion to the entire mixed layer unit.

5. Said organic light-emitting display apparatus as claimed in claim 4, wherein said luminescent dopant is triplet excited state phosphorescent emission, singlet excited state fluorescence emission, or thermally activated delayed fluorescence emission.

6. Said organic light-emitting display apparatus as claimed in claim 1, wherein a thickness of said first mixed layer is 10-500 Å, which is doped with the first functional doping material in a weight percent ratio of 1%-50%.

7. Said organic light-emitting display apparatus as claimed in claim 2, wherein a thickness of said second mixed layer is 10-500 Å.

8. Said organic light-emitting display apparatus as claimed in claim 3, wherein said second mixed layer is doped with the second functional doping material in a weight percent ratio of 1%-50%.

9. Said organic light-emitting display apparatus as claimed in claim 2, wherein in said organic light-emitting dielectric layer, the hole injection layer, the hole transporting layer, the first mixed layer, the emission layer, the electron transporting layer, the electron injection layer, and the second mixed layer all are made and formed by a vacuum deposition method, an inkjet printing method, a knife coating method, a spin coating method, or a screen printing method.

10. Said organic light-emitting display apparatus as claimed in claim 1, wherein said substrate is a TFT substrate;
in said organic light-emitting device, the anode layer, the organic light-emitting dielectric layer, and the cathode layer are sequentially disposed on said substrate from bottom to top; or
in said organic light-emitting device, the cathode layer, the organic light-emitting dielectric layer, and the anode layer are sequentially disposed on said substrate from bottom to top.

11. An organic light-emitting display apparatus comprising a substrate, and an organic light-emitting device disposed on the substrate;
said organic light-emitting device comprising an anode layer, a cathode layer, and an organic light-emitting dielectric layer disposed between the anode layer and the cathode layer;
said organic light-emitting dielectric layer comprising a hole injection layer, a hole transporting layer, a first mixed layer, an emission layer, an electron transporting layer, and an electron injection layer, which are sequentially disposed on said anode layer, nearly to a side of the cathode layer; and
said first mixed layer being a mixed material layer consisting of a bipolar host material and a first functional doping material; wherein said bipolar host material is a compound having a function of simultaneously transporting hole and electron; said first functional doping material is a material having an electron blocking function, a material having a hole control function, or both thereof in combination;
wherein a thickness of said first mixed layer is 10-500 Å, which is doped with the first functional doping material in a weight percent ratio of 1%-50%; and
wherein said substrate is a TFT substrate;
in said organic light-emitting device, the anode layer, the organic light-emitting dielectric layer, and the cathode layer are sequentially disposed on said substrate from bottom to top; or
in said organic light-emitting device, the cathode layer, the organic light-emitting dielectric layer, and the anode layer are sequentially disposed on said substrate from bottom to top.

12. Said organic light-emitting display apparatus as claimed in claim 11, wherein said organic light-emitting dielectric layer further comprises a second mixed layer disposed between said emission layer and the electron transporting layer; and said second mixed layer consists of the bipolar host material.

13. Said organic light-emitting display apparatus as claimed in claim 12, wherein said second mixed layer is a mixed material layer further consisting of a second functional doping material; wherein said second functional doping material is a material having a hole blocking function, a material having an electron control function, or both thereof in combination.

14. Said organic light-emitting display apparatus as claimed in claim 12, wherein said emission layer is a mixed material layer consisting of the bipolar host material and a luminescent dopant; and
said first mixed layer, the emission layer, and the second mixed layer commonly constitute a mixed layer unit; a thickness of said first mixed layer, a thickness of said second mixed layer do not respectively exceed one-third in a thickness proportion to the entire mixed layer unit.

15. Said organic light-emitting display apparatus as claimed in claim 14, wherein said luminescent dopant is triplet excited state phosphorescent emission, singlet excited state fluorescence emission, or thermally activated delayed fluorescence emission.

16. Said organic light-emitting display apparatus as claimed in claim 12, wherein a thickness of said second mixed layer is 10-500 Å.

17. Said organic light-emitting display apparatus as claimed in claim 13, wherein said second mixed layer is doped with the second functional doping material in a weight percent ratio of 1%-50%.

18. Said organic light-emitting display apparatus as claimed in claim 12, wherein in said organic light-emitting dielectric layer, the hole injection layer, the hole transporting layer, the first mixed layer, the emission layer, the electron transporting layer, the electron injection layer and the second mixed layer all are made and formed by a vacuum deposition method, an inkjet printing method, a knife coating method, a spin coating method, or a screen printing method.
